(19) United States
(12) Patent Application Publication
(10) Pub. No.: US 2026/0195505 A1
(43) Pub. Date: Jul. 9, 2026

(54) ANALYTICS-BASED UPGRADING OF INDUSTRIAL FLOOR

(71) Applicant: International Business Machines Corporation, Armonk, NY (US)

(72) Inventors: Sarbajit Kumar Rakshit, Kolkata (IN); Sudheesh S. Kairali, Kozhikode (IN); Binoy Thomas, Kozhikode (IN)

(21) Appl. No.: 19/010,265

(22) Filed: Jan. 6, 2025

(51) Int. Cl. G06F 30/27; G05B 13/04

(52) U.S. Cl. CPC G06F 30/27; G05B 13/04

(57) ABSTRACT

Examples described herein provide for analytics requirement-based upgrading of an industrial floor. Aspects include receiving a request for an analytical report and identifying the necessary data types. Aspects also includes obtaining a digital twin of the current industrial floor configuration, simulating the operation of the digital twin, and identifying data types not being obtained. Aspects further include using a trained machine learning module to identify changes to the current configuration to obtain the required data and autonomously performs these changes.

### BACKGROUND

The disclosure relates to industrial automation and data analytics, specifically to systems and methods for upgrading industrial floors based on analytics requirements.

Reports are important for industrial floors because they provide insights and information that aid in decision-making, performance evaluation, and process optimization. Reports for industrial floors are important for evaluating performance, optimizing processes, supporting decision-making, ensuring regulatory compliance, and enabling predictive maintenance. They play a role in driving operational efficiency, cost reduction, and overall success in industrial settings.

To perform different types of analysis on an industrial floor, various types of data need to be collected. The specific data required may vary depending on the industry and the specific analysis objectives. Examples of data collected from industrial floors include production data, sensor data, equipment data, quality control data, inventory and supply chain data, energy consumption data, safety and compliance data, workforce data, financial data, environmental data, camera data, wearable and IoT feeds from workers, and remote worker data.

### SUMMARY

According to one aspect of the present invention, a computer-implemented method for analytics requirement-based upgrading of an industrial floor comprises receiving a request for an analytical report for the industrial floor and identifying a plurality of types of data required for the analytical report for the industrial floor. The method further includes obtaining a digital twin of the current configuration of the industrial floor and simulating its operation based on this digital twin. It also involves identifying one or more of the plurality of types of data required for the analytical report for the industrial floor that are not being obtained during the operation of the industrial floor based on the simulation of the digital twin of the current configuration of the industrial floor. The method includes identifying, using a trained machine learning module, one or more changes to the current configuration of the industrial floor that will result in the one or more of the plurality of types of data required for the analytical report for the industrial floor that are being obtained during the operation of the industrial floor, and autonomously performing the one or more changes to the current configuration of the industrial floor.

The above features and advantages, and other features and advantages, of the disclosure are readily apparent from the following detailed description when taken in connection with the accompanying drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of one or more embodiments described herein are apparent from the following detailed description taken in conjunction with the accompanying drawings in which:

FIG. 1 illustrates a block diagram of a computing environment in accordance with an embodiment;

FIG. 2 illustrates a block diagram of a system for analytics requirement-based upgrading of an industrial floor in accordance with an embodiment; and

FIG. 3 illustrates a flow chart diagram of a method for analytics requirement-based upgrading of an industrial floor in accordance with an embodiment.

The detailed description explains embodiments of the disclosure, together with advantages and features, by way of example with reference to the drawings.

### DETAILED DESCRIPTION

Industrial floors rely heavily on analytical reports to provide insights and information that aid in decision-making, performance evaluation, and process optimization. These reports are crucial for evaluating performance, optimizing processes, supporting decision-making, ensuring regulatory compliance, and enabling predictive maintenance. The need for different types of analytics on an industrial floor necessitates the collection of various types of data, which may vary depending on the industry and specific analytical objectives. Examples of data collected from industrial floors include production data, sensor data, equipment data, quality control data, inventory and supply chain data, energy consumption data, safety and compliance data, workforce data, financial data, environmental data, camera data, wearable and IoT feeds from workers, and remote worker data. Current solutions for industrial data analysis often face limitations in accommodating the increasing diversity of data types captured from industrial floors. These solutions may lack the flexibility to dynamically synchronize with various activity stages to monitor agreed metrics and KPIs effectively. Additionally, existing systems may not provide the necessary adaptability for business users to select decision types and analyses, prompting corresponding adjustments in the industrial floor infrastructure to support evolving data capture and analysis requirements. As a result, there is a need for a more comprehensive and adaptable approach to upgrading industrial floors based on analytics requirements.

The present disclosure addresses these challenges by providing a method and system for analytics requirement-based upgrading of industrial floors. The disclosed system performs a comparative digital twin simulation of the current industrial floor with a reference virtual industrial floor where the selected or defined types of analysis are performed, or decisions are made. Based on this comparative analysis, the system identifies data insufficiencies in the current industrial floor and determines the additional data capturing methods required. The system utilizes a knowledge corpus, which includes historically captured reports, and the types of raw data and information considered for different reports and decision points. This knowledge corpus aids in creating a virtual second industrial floor based on the types of selected reports and decision points, enabling a comparative evaluation with the current industrial floor. The system then identifies the necessary input data collection systems to be deployed in different portions of the industrial floor, ensuring that the required types of analytical reports can be generated, and decisions can be made. Additionally, the system autonomously performs the necessary changes to the current configuration of the industrial floor, including deploying and configuring sensors and other input data collection systems.

Descriptions of various embodiments of the present disclosure are presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various aspects of the present disclosure are described by narrative text, flowcharts, block diagrams of computer systems, and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

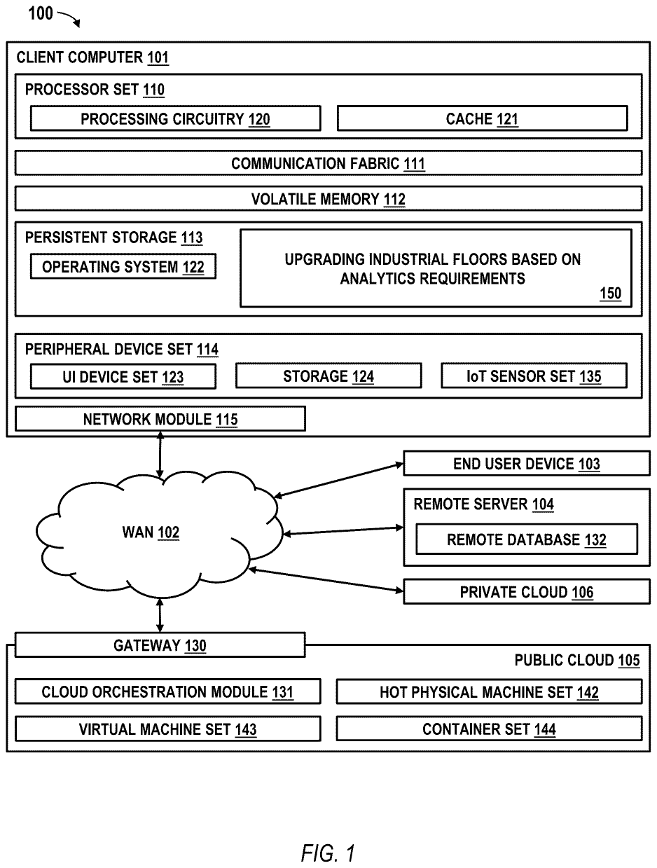

FIG. 1 illustrates a computing environment 100, according to an embodiment. Computing environment 100 contains an example of an environment for the execution of at least some of the computer code involved in performing the inventive methods, such as analytics requirement-based upgrading of an industrial floor, as shown at block 150. In addition to a controller for controlling the operations of a metal cutting tool, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in persistent storage 113 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

According to one or more embodiments, the computing environment 100 can provide for remote data storage. For example, the computer 101 can be a cloud storage system or other suitable system for storing data that is accessible to a user remotely, such as by accessing the computer 101 using the end user device 103. That is, a user can send a user operation (also referred to as a “user request”) from the end user device 103 to the computer 101 via the WAN 102. Although the user operation may appear to be simple, such as uploading an object to a cloud storage system, the complications of operating a cloud computing system often have side effects and produce ancillary data, which may be consumed by both the operator of the system (e.g., the computer 101) and by users or other components of the cloud architecture (e.g., the computing environment 100). Ancillary data may be created by user operations that trigger the creation of the ancillary data. Ancillary data may be resource consumption information, notification data, and/or the like, including combinations and/or multiples thereof. Data for an independent event may be inferred from another event (e.g., event to update resource consumption information for an entity in a system also means that the total consumption information for the owner of the entity is also updated).

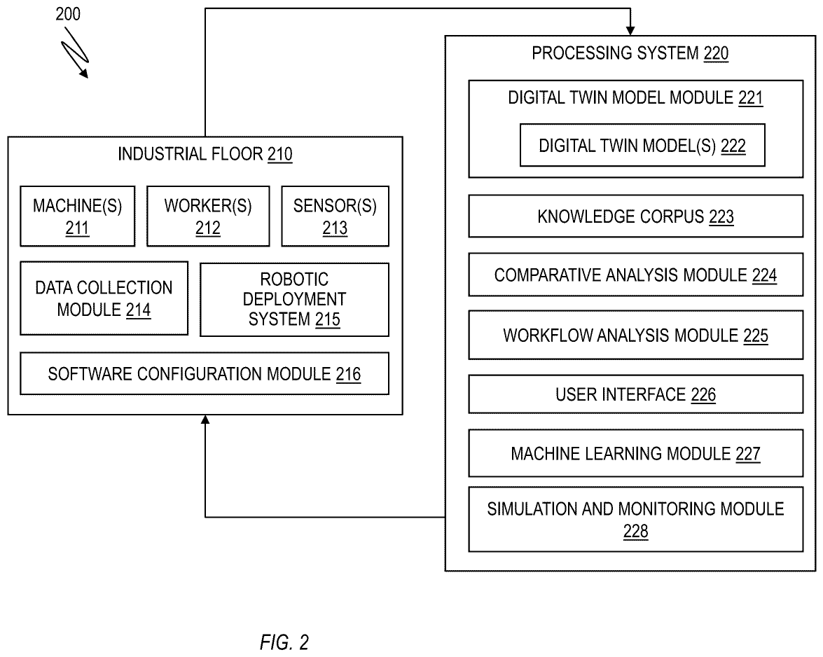

Referring now to FIG. 2, a block diagram of a system 200 for analytics requirement-based upgrading of an industrial floor is shown. The system 200 includes an industrial floor 210, which serves as the primary environment where the various activities and interactions take place. The industrial floor 210 encompasses the machinery, workers, and processes involved in the manufacturing or production activities. The industrial floor 210 is equipped with multiple machine(s) 211, which include various types of equipment and devices used in the manufacturing processes. These machines can range from simple mechanical devices to complex automated systems, including robots and AI-driven machinery. The machine(s) 211 perform specific tasks and operations integral to the production workflow.

In exemplary embodiments, one or more worker(s) 212 are present on the industrial floor. The workers 212 are the human operators who interact with the machine(s) 211 on the industrial floor 210. The worker(s) 212 perform various activities, such as operating machines, monitoring processes, and making decisions that impact the overall production.

In exemplary embodiments, sensor(s) 213 are deployed throughout the industrial floor 210 to collect data on the performance and status of the machine(s) 211 and the activities of the worker(s) 212. These sensors can include IoT devices, cameras, and other monitoring equipment that capture real-time information on the industrial processes. In one example, IoT sensors can be used to monitor machine parameters such as temperature, pressure, vibration, and operational status, providing real-time data on the health and performance of the equipment. Cameras can be strategically placed to capture visual data on worker activities, machine operations, and overall workflow, enabling the system to analyze worker movements, detect deviations from standard procedures, and identify potential safety hazards. Additionally, wearable sensors can be used to monitor worker biometrics, such as heart rate, body temperature, and fatigue levels, providing insights into worker well-being and potential impacts on performance. Proximity sensors can detect the presence and movement of workers around machines, ensuring safe interactions and preventing accidents. Environmental sensors can measure factors such as air quality, noise levels, and lighting conditions, which can affect worker performance and safety. By integrating data from these diverse sensors, the processing system 220 can create a comprehensive and real-time view of the industrial floor, enabling accurate analysis and visualization of skill gaps and their consequences.

In exemplary embodiments, the data collection module 214 aggregates the data collected by the sensor(s) 213 and other sources. The data collection module 214 is responsible for gathering, processing, and organizing data to ensure that all relevant information is available for further analysis. The data collection module 214 receives data from various types of sensors deployed throughout the industrial floor, including IoT devices, cameras, wearable sensors, proximity sensors, and environmental sensors. Each type of sensor provides specific data points that contribute to a comprehensive understanding of the industrial processes and worker activities.

In exemplary embodiments, the data collection module 214 processes the raw data by filtering out noise and irrelevant information, ensuring that only accurate and useful data is retained. This processing step may involve data cleaning techniques, such as removing duplicate entries, correcting errors, and normalizing data formats. The data collection module 214 then organizes the processed data into structured formats, such as databases or data warehouses, making it easier to access and analyze. Additionally, the data collection module 214 integrates data from other sources, such as historical performance records, maintenance logs, and real-time data streams from the industrial floor. This integration allows the module to create a unified dataset that encompasses all aspects of the industrial environment, including machine performance, worker activities, and environmental conditions. The data collection module 214 also ensures data synchronization and consistency across different sources. The data collection module 214 continuously updates the dataset with new information, maintaining an up-to-date view of the industrial floor.

In exemplary embodiments, the industrial floor 210 includes a robotic deployment system 215 that is configured to deploy the necessary input data collection systems and sensors 213 on the industrial floor 210. Based on the analysis performed by the processing system 220, the robotic deployment system 215 autonomously installs and configures sensors 213 and other data collection devices in different portions of the industrial floor. The robotic deployment system 215 ensures that the required types of data are captured to generate the necessary analytical reports and support decision-making processes.

For instance, the robotic deployment system 215 can receive instructions from the processing system 220 to install temperature sensors in specific areas of the industrial floor where heat-sensitive processes occur. The robotic system navigates to the designated locations, installs the sensors, and configures them to capture temperature data at specified intervals, ensuring proper calibration and positioning for accurate readings. Additionally, during a shift change, the processing system 220 might identify a need to monitor worker movements in a different section of the industrial floor. The robotic deployment system 215 can autonomously relocate existing proximity sensors to the new area, ensuring continuous monitoring without manual intervention.

Moreover, the processing system 220 may determine that monitoring worker biometrics is crucial for a specific task. In such cases, the robotic deployment system 215 can distribute wearable devices to workers at the beginning of their shift, ensuring that the devices are properly configured to capture biometric data such as heart rate and body temperature. For environmental monitoring, the processing system 220 might identify a need to monitor air quality in a section of the industrial floor where chemical processes are conducted. The robotic deployment system 215 can deploy air quality sensors in the designated area, configure them to capture data on pollutants and particulate matter, and ensure data transmission to the processing system for analysis.

In scenarios involving predictive maintenance, the processing system 220 can predict potential equipment failure based on historical data and instruct the robotic deployment system 215 to install vibration sensors on critical machinery. The robotic system navigates to the machinery, installs the sensors, and configures them to monitor vibration levels continuously, allowing for early detection of anomalies and timely maintenance. For safety enhancements, the processing system 220 might identify a high-risk area where worker safety needs to be improved. The robotic deployment system 215 can install additional cameras and proximity sensors to monitor worker movements and ensure compliance with safety protocols, integrating the data with the processing system for continuous safety monitoring.

Furthermore, the processing system 220 may determine that data collection intervals need to be optimized for energy consumption monitoring. The robotic deployment system 215 can adjust the configuration of existing energy consumption sensors, autonomously reconfiguring them to capture data at optimized intervals, ensuring efficient data collection without compromising accuracy. These examples illustrate how the robotic deployment system 215 operates autonomously to install, configure, and reconfigure input data collection systems and sensors on the industrial floor 210. By leveraging the capabilities of the robotic deployment system, the industrial floor can dynamically adapt to evolving data capture and analysis requirements, ensuring continuous optimization and support for decision-making processes.

In exemplary embodiments, the industrial floor 210 includes a software configuration module 216 that is configured to manage the software aspects of the data collection systems and sensors 213 deployed on the industrial floor 210. The software configuration module 216 identifies the necessary software configurations and upgrades required to support the data collection and analysis processes. The software configuration module 216 ensures that the data collection systems are properly configured to capture the required data, including adjusting data generation frequencies, recalibrating sensors, and modifying data storage formats.

In exemplary embodiments, the system 200 also includes a processing system 220 that is the central component responsible for analyzing the data collected from the industrial floor 210. The processing system 220 utilizes various modules, including the digital twin model module 221, knowledge corpus 223, comparative analysis module 224, workflow analysis module 225, machine learning module 227, and simulation and monitoring module 228, to perform comprehensive analysis and generate insights. The processing system 220 processes the data to identify data insufficiencies, determine necessary changes to the industrial floor configuration, and support decision-making processes.

In exemplary embodiments, the digital twin model module 221 creates and manages digital twin models of the industrial floor 210. The digital twin model(s) 222 represent virtual replicas of the physical industrial floor, including the machines, workers, and processes. The digital twin model module 221 uses data from the sensor(s) 213 and other sources to create accurate and up-to-date digital twin models. These models are used for simulating and analyzing the industrial floor's operations, identifying data insufficiencies, and determining necessary changes to the configuration.

In exemplary embodiments, the digital twin model(s) 222 are virtual representations of the industrial floor 210, created and managed by the digital twin model module 221. These models replicate the physical layout, machines, workers, and processes of the industrial floor. The digital twin model(s) 222 are used for simulating the industrial floor's operations, analyzing performance, and identifying data insufficiencies. The digital twin model(s) 222 enable comparative analysis with a reference virtual industrial floor to determine necessary changes and improvements.

In exemplary embodiments, the knowledge corpus 223 is a repository of historically captured reports, raw data, and information considered for different reports and decision points. The knowledge corpus 223 aids in creating virtual second industrial floors based on the types of selected reports and decision points. This repository is used by the processing system 220 to perform comparative evaluations with the current industrial floor, identify data insufficiencies, and determine necessary changes to the configuration.

In exemplary embodiments, the comparative analysis module 224 performs comparative evaluations between the current industrial floor and the reference virtual industrial floor. The comparative analysis module 224 module uses the digital twin model(s) 222 and the knowledge corpus 223 to identify data insufficiencies and determine the additional data capturing methods required. The comparative analysis module 224 ensures that the necessary input data collection systems are deployed to generate the required analytical reports and support decision-making processes.

In exemplary embodiments, the workflow analysis module 225 analyzes the workflows and processes on the industrial floor 210. The workflow analysis module 225 identifies different stages of activities, the required metrics and KPIs, and the necessary input data collection systems. The workflow analysis module 225 ensures that the data collection systems are properly configured to capture the required data for each stage of the workflow, supporting accurate analysis and decision-making.

In exemplary embodiments, the user interface 226 provides a platform for business users to interact with the system 200. The user interface 226 allows users to define the types of analytical reports they want to execute and the decisions they want to make. The user interface 226 displays the results of the analysis performed by the processing system 220, including insights, recommendations, and necessary changes to the industrial floor configuration. The user interface 226 ensures that users can easily access and utilize the system's capabilities to support their decision-making processes.

In exemplary embodiments, the machine learning module 227 is responsible for training and utilizing machine learning models to analyze the data collected from the industrial floor 210. The machine learning module 227 uses the knowledge corpus 223 to train models on historically captured reports and raw data information. The machine learning module 227 identifies patterns, trends, and correlations in the data, supporting the identification of data insufficiencies and necessary changes to the industrial floor configuration. The machine learning module 227 ensures that the system 200 can adapt to evolving data capture and analysis requirements.

In exemplary embodiments, the simulation and monitoring module 228 performs simulations of the industrial floor's operations based on the digital twin model(s) 222. The simulation and monitoring module 228 module monitors the real-time data collected from the sensor(s) 213 and other sources, ensuring that the simulations accurately reflect the current state of the industrial floor. The simulation and monitoring module 228 identifies data insufficiencies, evaluates the impact of proposed changes, and supports the decision-making processes. The simulation and monitoring module 228 ensures that the system 200 can continuously adapt and optimize the industrial floor's operations.

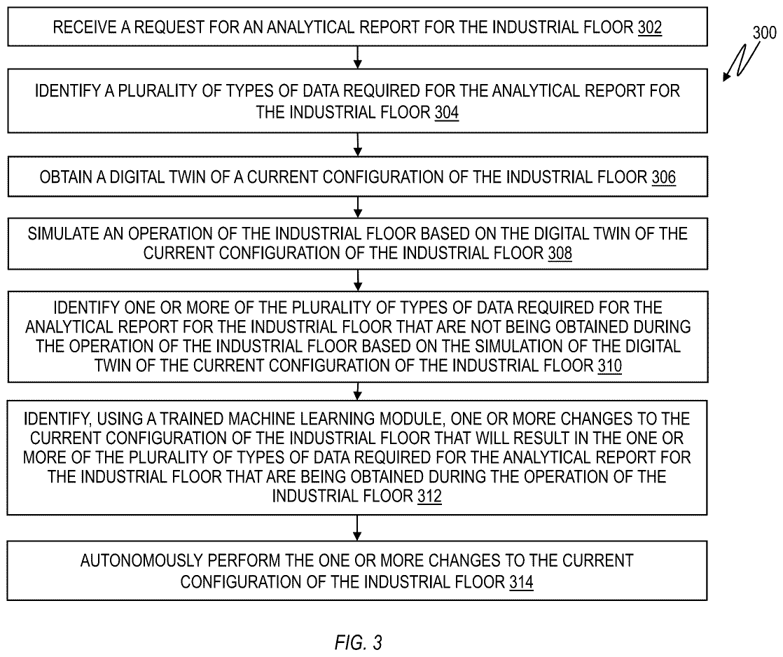

Referring now to FIG. 3, a flow chart illustrating a method 300 for analytics requirement-based upgrading of an industrial floor is shown. In exemplary embodiments, the method 300 can be implemented by the system 200 as described in FIG. 2. The method 300 begins with receiving a request on an analytical report for the industrial floor, as shown at block 302. In exemplary embodiments, the method is initiated by business users through the user interface 226 submitting a request for an analytical report. The request specifies the types of analytical reports needed and the decisions that users want to make based on the analysis. The processing system 220 captures this request and begins identifying the necessary data and configurations required to generate the requested reports.

Next, as shown at block 304, the method 300 includes identifying a plurality of types of data required for the analytical report. In exemplary embodiments, identifying a plurality of types of data required for the analytical report involves analyzing the request to determine the specific data points and metrics needed. The processing system 220 utilizes the knowledge corpus 223, which contains historically captured reports and raw data information, to identify the relevant data types, ensuring that all necessary data is considered for the analysis.

Next, as shown at block 306, the method 300 includes obtaining a digital twin of the current configuration of the industrial floor. In exemplary embodiments, the digital twin model module 221 creates and manages digital twin models of the industrial floor 210, representing virtual replicas of the physical industrial floor, including machines, workers, and processes. These models are used for simulating and analyzing the industrial floor's operations.

After obtaining the digital twin, the method 300 includes simulating an operation of the industrial floor based on the digital twin of the current configuration, as shown at block 308. In exemplary embodiments, the simulation and monitoring module 228 performs simulations using the digital twin model(s) 222, helping to understand the current state of the industrial floor and identify any data insufficiencies or gaps in the data collection process. Based on the simulation, the method includes identifying one or more types of data required for the analytical report that are not being obtained during the operation of the industrial floor, as shown at block 310. In exemplary embodiments, the comparative analysis module 224 performs evaluations between the current industrial floor and reference virtual industrial floor to identify data insufficiencies, ensuring that any missing data points are identified and the necessary data capturing methods are determined.

Next, as shown at block 312, the method 300 includes using a trained machine learning module 227 to identify changes to the current configuration of the industrial floor that will result in obtaining the required data. In exemplary embodiments, the machine learning module 227 uses the knowledge corpus 223 to train models on historically captured reports and raw data information, identifying patterns, trends, and correlations in the data to support the identification of necessary changes. This step ensures that the system can adapt to evolving data capture and analysis requirements.

At block 314, the method 300 includes autonomously performing the identified changes to the current configuration of the industrial floor. The robotic deployment system 215 is configured to deploy the necessary input data collection systems and sensors 213 on the industrial floor 210. Based on the analysis performed by the processing system 220, the robotic deployment system 215 autonomously installs and configures sensors and other data collection devices in different portions of the industrial floor, ensuring that the required types of data are captured to generate the necessary analytical reports and support decision-making processes.

In exemplary embodiments, the method 300 also includes creating an updated digital twin of the industrial floor that incorporates the identified changes to the current configuration. After the initial digital twin simulation identifies data insufficiencies and the necessary changes are determined, the system updates the digital twin model to reflect these modifications. This updated digital twin includes newly deployed sensors, reconfigured data collection systems, and any other adjustments made to the industrial floor. The system then simulates the operation of the industrial floor based on this updated digital twin, ensuring that the changes effectively address the previously identified data gaps. By verifying that each type of data required for the analytical report is now being obtained during the operation of the industrial floor, the system ensures that the modifications are successful and that the industrial floor is optimized for accurate data collection and analysis. This embodiment allows for continuous improvement and validation of the industrial floor's configuration, providing a robust framework for dynamic adaptation to evolving analytics requirements.

In one example, the processing system 220 identifies that temperature data is needed for generating an analytical report on the efficiency of heat-sensitive processes within the industrial floor. During the simulation of the digital twin, it becomes apparent that the current configuration lacks sufficient temperature sensors in key areas where these processes occur. The comparative analysis module 224 highlights this data insufficiency, and the machine learning module 227 determines that additional temperature sensors need to be deployed. The robotic deployment system 215 is then instructed to install these sensors in the identified areas, ensuring that accurate temperature data is captured during the operation of the industrial floor. This additional data allows for a comprehensive analysis of the heat-sensitive processes, leading to more informed decision-making and process optimization.

In another example, the processing system 220 identifies that data on worker movements is essential for an analytical report focused on improving safety protocols and reducing workplace accidents. The simulation of the digital twin reveals that the current configuration does not adequately monitor worker movements in high-risk areas. The comparative analysis module 224 identifies this gap, and the machine learning module 227 suggests deploying additional proximity sensors and cameras in these critical zones. The robotic deployment system 215 autonomously installs and configures these sensors, ensuring continuous monitoring of worker activities. This enhanced data collection enables the generation of detailed safety reports, allowing for the implementation of targeted safety measures and protocols to mitigate risks and enhance worker safety on the industrial floor.

In one embodiment, the software configuration module 216 autonomously adjusts the frequency of data generation by the sensors to optimize data collection intervals. For instance, in a high-precision manufacturing environment, the software configuration module 216 may increase the data collection frequency of temperature sensors during phases of production to ensure real-time monitoring and control. During less significant phases, the software configuration module 216 may reduce the frequency to conserve energy and reduce data storage requirements. I n another embodiment, the software configuration module 216 recalibrates the sensors to enhance the precision and accuracy of the collected data. For example, in a pharmaceutical manufacturing process, the software configuration module 216 might recalibrate humidity sensors to ensure they provide accurate readings for maintaining product quality. This recalibration can be performed periodically or triggered by detected anomalies in the sensor data. Additionally, in a further embodiment, the software configuration module 216 modifies the data storage format used by the sensors to ensure compatibility with different data analysis tools. For example, in an automotive assembly line, the software configuration module 216 might convert data from proprietary sensor formats to standardized formats like JSON or XML, facilitating seamless integration with various analytics platforms and tools.

In an example scenario, a manufacturing company operating an industrial floor receives a request for an analytical report to evaluate the efficiency of its heat-sensitive production processes. The request is initiated by business users through the user interface, specifying the need for detailed temperature data to make informed decisions about process optimization.

Following the method outlined in FIG. 3, the system first identifies the types of data required for the analytical report, which includes temperature data from various critical points on the industrial floor. The system then obtains a digital twin of the current configuration of the industrial floor, creating a virtual replica that includes all machines, workers, and processes.

Next, the system simulates the operation of the industrial floor based on the digital twin. During this simulation, it becomes apparent that the current configuration lacks sufficient temperature sensors in key areas where heat-sensitive processes occur. The comparative analysis module identifies this data insufficiency, and the machine learning module determines that additional temperature sensors need to be deployed.

Using the trained machine learning module, the system identifies the specific changes required to the current configuration of the industrial floor. This includes the deployment of additional temperature sensors in the identified areas. The robotic deployment system is then instructed to autonomously install these sensors, ensuring they are properly calibrated and positioned to capture accurate temperature data.

Once the sensors are deployed, the system updates the digital twin to reflect these modifications and simulates the operation of the industrial floor again. This updated simulation verifies that the required temperature data is now being captured during the operation. The collected data is then used to generate the comprehensive analytical report, providing insights into the efficiency of the heat-sensitive processes and enabling the company to make informed decisions for process optimization.

In exemplary embodiments, methods and systems for updating an industrial floor based on analytics requirements are provided. By receiving a request for an analytical report and identifying the necessary data types, the disclosed method ensures that all relevant data points are considered for comprehensive analysis. The use of a digital twin of the current configuration of the industrial floor allows for accurate simulation of operations, providing a virtual environment to identify data insufficiencies without disrupting actual production processes. The simulation of the digital twin is configured to identify specific data types that are not being captured during the operation. By leveraging a trained machine learning module, the method identifies precise changes needed in the current configuration to ensure that all necessary data is obtained. The autonomous execution of these changes, including the deployment and configuration of sensors and other data collection systems, ensures that the industrial floor is continuously optimized for data collection and analysis. This automation reduces the need for manual intervention, thereby minimizing human error and increasing efficiency. The method's ability to dynamically adapt to evolving data capture requirements supports ongoing process optimization and decision-making, ultimately enhancing operational efficiency and productivity on the industrial floor.

The invention significantly improves the functioning of the processing system 220 by enhancing its ability to dynamically adapt to evolving data capture and analysis requirements on the industrial floor. By incorporating a digital twin model module, the processing system 220 can create and manage accurate virtual replicas of the industrial floor, including machines, workers, and processes. This capability allows the processing system to simulate operations and identify data insufficiencies without disrupting actual production processes, leading to more informed decision-making and process optimization.

The integration of a knowledge corpus within the processing system 220 further enhances its functionality. This repository of historically captured reports, raw data, and decision points enables the processing system to perform comparative evaluations with the current industrial floor. By leveraging this historical data, the processing system can identify patterns, trends, and correlations, which are crucial for determining necessary changes to the industrial floor configuration. The inclusion of a machine learning module within the processing system 220 allows for the training and utilization of machine learning models to analyze the collected data. This module identifies data insufficiencies and necessary changes to the industrial floor configuration, ensuring that the system can adapt to evolving data capture and analysis requirements. The machine learning module's ability to learn from historical data and make predictions based on patterns and trends significantly enhances the processing system's analytical capabilities.

The processing system 220 also benefits from the workflow analysis module, which analyzes the workflows and processes on the industrial floor. This module identifies different stages of activities, the required metrics and KPIs, and the necessary input data collection systems. By ensuring that the data collection systems are properly configured to capture the required data for each stage of the workflow, the processing system can support accurate analysis and decision-making. Furthermore, the simulation and monitoring module within the processing system 220 performs real-time simulations of the industrial floor's operations based on the digital twin models. This module monitors the data collected from various sensors and other sources, ensuring that the simulations accurately reflect the current state of the industrial floor. By identifying data insufficiencies and evaluating the impact of proposed changes, the simulation and monitoring module supports continuous adaptation and optimization of the industrial floor's operations.

While the foregoing is directed to embodiments of the present disclosure, other and further embodiments of the present disclosure may be devised without departing from the basic scope thereof, and the scope thereof is determined by the claims that follow.

What is claimed is:

1. A computer-implemented method for analytics requirement-based upgrading of an industrial floor, the method comprising:
receiving a request for an analytical report for the industrial floor;
identifying a plurality of types of data required for the analytical report for the industrial floor;
obtaining a digital twin of a current configuration of the industrial floor;
simulating an operation of the industrial floor based on the digital twin of the current configuration of the industrial floor;
identifying one or more of the plurality of types of data required for the analytical report for the industrial floor that are not being obtained during the operation of the industrial floor based on the simulation of the digital twin of the current configuration of the industrial floor;
identifying, using a trained machine learning module, one or more changes to the current configuration of the industrial floor that will result in the one or more of the plurality of types of data required for the analytical report for the industrial floor that are being obtained during the operation of the industrial floor; and
autonomously performing the one or more changes to the current configuration of the industrial floor.

2. The computer-implemented method of claim 1, further comprising:
creating an updated digital twin of the industrial floor that includes the one or more changes to the current configuration of the industrial floor; and
simulating the operation of the industrial floor based on the updated digital twin of the current configuration of the industrial floor.

3. The computer-implemented method of claim 2, further comprising verifying that each of the plurality of types of data required for the analytical report for the industrial floor that are being obtained during the operation of the industrial floor based on the simulation of the updated digital twin of the industrial floor.

4. The computer-implemented method of claim 1, wherein the trained machine learning module is trained using a knowledge corpus of historically captured reports and raw data information.

5. The computer-implemented method of claim 1, wherein autonomously performing the one or more changes to the current configuration of the industrial floor includes deploying one or more sensors in different portions of the industrial floor using a robotic system.

6. The computer-implemented method of claim 1, wherein autonomously performing the one or more changes to the current configuration of the industrial floor includes updating a configuration of one or more sensors deployed in the industrial floor.

7. The computer-implemented method of claim 6, wherein the configuration update includes one or more of:
adjusting a frequency of data generation by the one or more sensors to optimize data collection intervals;
recalibrating the one or more sensors to enhance a precision and accuracy of the collected data; and
modifying a data storage format used by the one or more sensors to ensure compatibility with different data analysis tools.

8. A system comprising:
a memory comprising computer readable instructions; and
a processing device for executing the computer readable instructions, the computer readable instructions controlling the processing device to perform operations comprising:
receiving a request for an analytical report for an industrial floor;
identifying a plurality of types of data required for the analytical report for the industrial floor;
obtaining a digital twin of a current configuration of the industrial floor;
simulating an operation of the industrial floor based on the digital twin of the current configuration of the industrial floor;
identifying one or more of the plurality of types of data required for the analytical report for the industrial floor that are not being obtained during the operation of the industrial floor based on the simulation of the digital twin of the current configuration of the industrial floor;
identifying, using a trained machine learning module, one or more changes to the current configuration of the industrial floor that will result in the one or more of the plurality of types of data required for the analytical report for the industrial floor that are being obtained during the operation of the industrial floor; and
autonomously performing the one or more changes to the current configuration of the industrial floor.

9. The system of claim 8, wherein the digital twin of the current configuration of the industrial floor includes virtual replicas of machines, workers, and processes on the industrial floor.

10. The system of claim 9, wherein the digital twin model includes real-time data synchronization with the industrial floor.

11. The system of claim 9, wherein the operations further comprise creating an updated digital twin of the industrial floor that includes the one or more changes to the current configuration of the industrial floor.

12. The system of claim 11, wherein the operations further comprise simulating the operation of the industrial floor based on the updated digital twin of the current configuration of the industrial floor.

13. The system of claim 12, wherein the operations further comprise verifying that each of the plurality of types of data required for the analytical report for the industrial floor that are being obtained during the operation of the industrial floor based on the simulation of the updated digital twin of the industrial floor.

14. The system of claim 8, wherein the trained machine learning module is trained using a knowledge corpus of historically captured reports and raw data information.

15. The system of claim 8, wherein autonomously performing the one or more changes to the current configuration of the industrial floor includes deploying one or more sensors in different portions of the industrial floor using a robotic system.

16. The system of claim 8, wherein autonomously performing the one or more changes to the current configuration of the industrial floor includes updating a configuration of one or more sensors deployed in the industrial floor.

17. A computer program product for visualizing consequences of skill gaps by a worker on an industrial floor the computer program product comprising:
a set of one or more computer-readable storage media;
program instructions, collectively stored in the set of one or more storage media, for causing a processor set to perform the following computer operations:
receiving a request for an analytical report for an industrial floor;
identifying a plurality of types of data required for the analytical report for the industrial floor;
obtaining a digital twin of a current configuration of the industrial floor;
simulating an operation of the industrial floor based on the digital twin of the current configuration of the industrial floor;
identifying one or more of the plurality of types of data required for the analytical report for the industrial floor that are not being obtained during the operation of the industrial floor based on the simulation of the digital twin of the current configuration of the industrial floor;
identifying, using a trained machine learning module, one or more changes to the current configuration of the industrial floor that will result in the one or more of the plurality of types of data required for the analytical report for the industrial floor that are being obtained during the operation of the industrial floor; and
autonomously performing the one or more changes to the current configuration of the industrial floor.

18. The computer program product of claim 17, wherein the operations further comprise creating an updated digital twin of the industrial floor that includes the one or more changes to the current configuration of the industrial floor.

19. The computer program product of claim 18, wherein the operations further comprise simulating the operation of the industrial floor based on the updated digital twin of the current configuration of the industrial floor.

20. The computer program product of claim 19, wherein the operations further comprise verifying that each of the plurality of types of data required for the analytical report for the industrial floor that are being obtained during the operation of the industrial floor based on the simulation of the updated digital twin of the industrial floor.
